(19) United States
(12) Patent Application Publication
(10) Pub. No.: US 2026/0064214 A1
(43) Pub. Date: Mar. 5, 2026

(54) TOUCHSCREEN ACTUATING DEVICES, AND SYSTEMS, AND METHODS COMPRISING SAME

(71) Applicant: Nott Company, Arden Hills, MN (US)

(72) Inventors: Dusten Carl O'Konek, Jr., Henderson, MN (US); Anthony Reid Hennum, Shakopee, MN (US); Andrew Nowak, Lakeville, MN (US)

(21) Appl. No.: 19/312,921

(22) Filed: Aug. 28, 2025

Related U.S. Application Data
(60) Provisional application No. 63/687,958, filed on Aug. 28, 2024.

(51) Int. Cl. G06F 3/039; G06F 3/044

(52) U.S. Cl. CPC G06F 3/0393; G06F 3/044

(57) ABSTRACT

A device is configured for use with a capacitive touch surface. The device includes at least one button, the at least one button including a first surface that is configured to contact the capacitive touch surface and a second surface opposite the first surface along a first axis. The at least one button is configured so that application of a force against the second surface causes the first surface to move from a first position in a first direction along the first axis and release of the force permits the first surface to return to the first position. The at least one button further includes a conductive material that is sufficient to actuate the capacitive touch surface upon contact between the conductive material and the capacitive touch surface. The conductive material is positioned between the first surface and the second surface.

### CROSS-REFERENCE TO RELATED APPLICATIONS

This application claims the benefit of U.S. Provisional Patent Application No. 63/687,958, filed August 28, 2024, the entirety of which is hereby incorporated by reference herein.

### FIELD

The disclosure relates to devices, systems, and methods for actuating touchscreens.

### BACKGROUND

Capacitive touch surfaces, such as touch screens and touch pads, have become increasingly prevalent in a variety of applications, including but not limited to, consumer electronics, industrial controls, and automotive interfaces. These touch surfaces operate based on the principle of capacitive sensing, which detects changes in an electrical field caused by the proximity or contact of a conductive object, such as a human finger.

In capacitive touch surfaces, an array of capacitive sensors is embedded beneath the surface of the screen or pad. Each sensor is capable of detecting changes in capacitance caused by the approach or touch of a conductive object. The sensors generate signals corresponding to these changes, which are then processed by a controller to determine the location and nature of the touch event.

One common type of capacitive touch surface is the projected capacitive touch screen, which employs a grid of micro-fine wires or conductive traces layered on or within the glass of the screen. When a conductive object, such as a finger, comes into contact with or near the screen, it alters the electrostatic field and changes the capacitance at that point on the grid. This change is detected and processed by the controller to determine the exact location of the touch.

Despite the widespread use and advantages of capacitive touch surfaces, such as their ability to support multi-touch input and their high sensitivity and accuracy, they also have some limitations. For instance, they require direct contact with a conductive object, typically a bare finger, to operate. This can be impractical or even unsafe in some environments, such as in extreme cold where gloves are worn, or in industrial settings where operators may wear protective equipment. Furthermore, while capacitive touch surfaces offer a sleek and modern interface, they lack the tactile feedback provided by physical buttons and dials, which some users prefer or require for effective operation.

Accordingly, there is a need for an improved way to operate touch screens and touch pads.

### SUMMARY

Disclosed herein is a device for use with a capacitive touch surface. The device includes at least one button, the at least one button including a first surface that is configured to contact the capacitive touch surface and a second surface opposite the first surface along a first axis. The at least one button is configured so that application of a force against the second surface causes the first surface to move from a first position in a first direction along the first axis and release of the force permits the first surface to return to the first position. The at least one button further includes a conductive material that is sufficient to actuate the capacitive touch surface upon contact between the conductive material and the capacitive touch surface. The conductive material is positioned between the first surface and the second surface.

Also disclosed herein are assemblies and systems using the device.

### BRIEF DESCRIPTION OF DRAWINGS

The invention will now be described, by way of example, with reference to the accompanying drawings in which:

FIG. 1 is schematic side view of a system comprising a capacitive touch surface and a device for use with the capacitive touch surface as disclosed herein, with all buttons of the device in respective home positions.

FIG. 2 is schematic side view of a system comprising a capacitive touch surface and a device for use with the capacitive touch surface as disclosed herein, wherein one button is displaced from the home position.

FIG. 3 is a front view of a device for use with a capacitive touch surface as disclosed herein.

FIG. 4 is an exploded view of the device of FIG. 3.

FIG. 5 is a front view of another embodiment of a device for use with a capacitive touch surface as disclosed herein.

FIG. 6 is an exploded view of the device of FIG. 5, showing rear perspective views of certain elements.

FIG. 7 is an exploded view of the device of FIG. 5, showing front perspective views of certain elements.

FIG. 8 is a front view of a device for use with a capacitive touch surface as disclosed herein.

FIG. 9 is an exploded view of the device of FIG. 8.

FIG. 10 is a schematic cross-section of the conductive layer of the device of FIG. 8

FIG. 11 is a schematic diagram of an exemplary dial as disclosed herein.

FIG. 12 is a schematic diagram of an exemplary switch as disclosed herein.

FIG. 13 is a block diagram of an exemplary computing system comprising a computing device as disclosed herein.

### DETAILED DESCRIPTION OF EMBODIMENTS

Before the present systems and methods are described, it is to be understood that the present disclosure is not limited to the particular processes, compositions, or methodologies described, as these may vary. It is also to be understood that the terminology used in the description is for the purposes of describing the particular versions or embodiments only, and is not intended to limit the scope of the present disclosure. Unless defined otherwise, all technical and scientific terms used herein have the same meanings as commonly understood by one of ordinary skill in the art. Although any methods and materials similar or equivalent to those described herein can be used in the practice or testing of embodiments of the present disclosure, the methods, devices, and materials in some embodiments are now described. All publications mentioned herein are incorporated by reference in their entirety. Nothing herein is to be construed as an admission that the present disclosure is not entitled to antedate such disclosure by virtue of prior invention.

### Definitions

Unless otherwise defined herein, scientific and technical terms used in connection with the present disclosure shall have the meanings that are commonly understood by those of ordinary skill in the art. The meaning and scope of the terms should be clear. However, in the event of any latent ambiguity, definitions provided herein take precedent over any dictionary or extrinsic definition. Further, unless otherwise dictated by context, singular terms shall include pluralities and plural terms shall include the singular.

The indefinite articles “a” and “an,” as used herein in the specification and in the claims, unless clearly indicated to the contrary, should be understood to mean “at least one.” The phrase “and/or,” as used herein in the specification and in the claims, should be understood to mean “either or both” of the elements so conjoined, i.e., elements that are conjunctively present in some cases and disjunctively present in other cases. Other elements may optionally be present other than the elements specifically identified by the “and/or” clause, whether related or unrelated to those elements specifically identified unless clearly indicated to the contrary. Thus, as a non-limiting example, a reference to “A and/or B,” when used in conjunction with open-ended language such as “comprising” can refer, in one embodiment, to A without B (optionally including elements other than B); in another embodiment, to B without A (optionally including elements other than A); in yet another embodiment, to both A and B (optionally including other elements); etc.

As used herein in the specification and in the claims, “or” should be understood to have the same meaning as “and/or” as defined above unless context dictates otherwise. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, “either,” “one of,” “only one of,” or “exactly one of.” “Consisting essentially of,” when used in the claims, shall have its ordinary meaning as used in the field of patent law.

The term “about” is used herein to mean within the typical ranges of tolerances in the art. For example, “about” can be understood as about 2 standard deviations from the mean. According to certain embodiments, when referring to a measurable value such as an amount and the like, “about” is meant to encompass variations of ±20%, ±10%, ±5%, ±1%, ±0.9%, ±0.8%, ±0.7%, ±0.6%, ±0.5%, ±0.4%, ±0.3%, ±0.2% or ±0.1% from the specified value as such variations are appropriate to perform the disclosed methods. When “about” is present before a series of numbers or a range, it is understood that “about” can modify each of the numbers in the series or range.

The term “at least” prior to a number or series of numbers (e.g. “at least two”) is understood to include the number adjacent to the term “at least,” and all subsequent numbers or integers that could logically be included, as clear from context. When “at least” is present before a series of numbers or a range, it is understood that “at least” can modify each of the numbers in the series or range. Ranges provided herein are understood to include all individual integer values and all subranges within the ranges.

As used herein, the terms “comprising” (and any form of comprising, such as “comprise,” “comprises,” and “comprised”), “having” (and any form of having, such as “have” and “has”), “including” (and any form of including, such as “includes” and “include”), or “containing” (and any form of containing, such as “contains” and “contain”), are inclusive or open-ended and do not exclude additional, unrecited elements or method steps.

### Device for use with Capacitive Touch Surface

Overlay devices disclosed herein can be used with a device containing one or more capacitive touch elements, such as a screen or touch pad (collectively herein referred to as “capacitive touch surfaces”), to allow a user to operate the capacitive touch element(s) of the capacitive touch surface without the need for direct finger contact with the screen or touch pad. Instead, the overlay device can provide one or more features for device actuation. For example, the overlay device can comprise one or more buttons or dials that the operator can engage to actuate the capacitive touch surfaces. To mimic the action of a finger touch, the button overlay can use a conductive material, such as, for example, a conductive elastomer or a rigid conductive material that mimics the conductivity of human skin and a non-conductive material for insulation. Although embodiments are described herein as being for use with capacitive touch surfaces, it is further contemplated that the disclosed device can be used with other touch surfaces, such as resistive touch surfaces.

The device gives operators the ability to use tactile controls on systems that previously were touch only, eliminating the need to replace such systems with tactile controls. Further, the device allows a user to operate the touch portion of the device without the need for direct finger contact with the screen or touch pad. For example, the overlay can permit device actuation through input elements (e.g., one or more buttons, dials, switches, sliders, etc.) that the operator can engage.

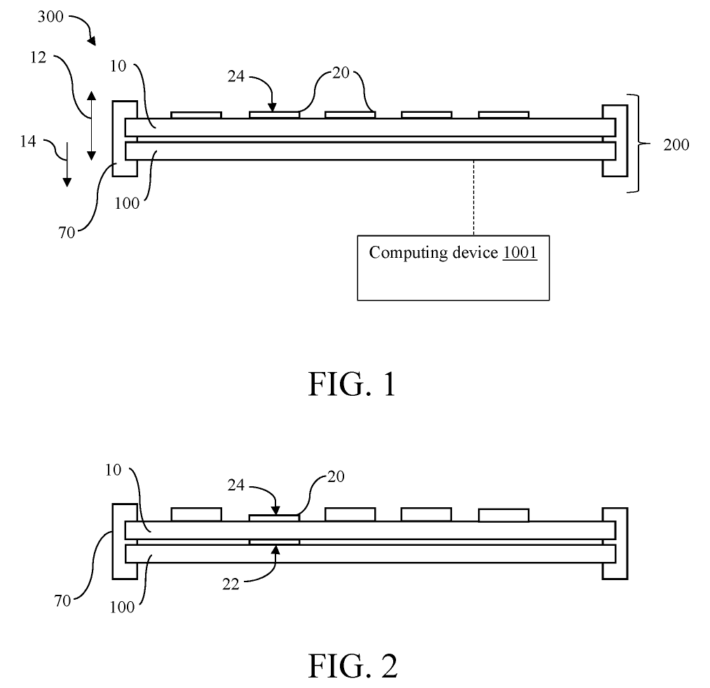

Referring to FIGS. 1-2, a device 10 for use with a capacitive touch surface 100 can comprise at least one button 20. The at least one button 20 can comprise a first surface 22 that is configured to contact the capacitive touch surface 100 and a second surface 24 opposite the first surface along a first axis 12. The at least one button 20 can be configured so that application of a force against the second surface causes the first surface 22 to move from a first position (FIG. 1) in a first direction 14 along the first axis 12 (FIG. 2). Release of the force can permit the first surface of the at least one button 20 to return to the first position (FIG. 1). The at least one button 20 can comprise a conductive material 30 that is sufficient to actuate the capacitive touch surface upon contact between the conductive material and the capacitive touch surface. The conductive material 30 can be positioned between the first surface 22 and the second surface 24. Optionally, in these aspects, the conductive material 30 can define the first surface 22. In other aspects, a coating can be applied to the surface of the conductive material 30 facing the first surface 22. The coating can be sufficiently thin that the conductive material can be positioned within sufficient proximity of the touchscreen to activate the touch surface. In such optional embodiments including a coating, the coating can be a protective coating to protect the touchscreen.

Accordingly, the force can cause the first surface 22 to come into contact with and actuate the capacitive touch surface. The conductive material 30 can itself be configured to mimic the conductivity of skin. This can contrast, for example, with a conductive material that merely conducts therethrough the properties of the skin of the user. In this way, advantageously, the device 10 can be operated by a user wearing gloves that insulate the skin of the user from the device 10.

It is further contemplated that each button 20 can be configured so that a sufficient area contacts the capacitive touch surface 100 upon application of the force. That is, it is contemplated that actuation of the capacitive touch surface 100 can be a function of the electrical properties (e.g., conductivity) of the conductive material 30 and the area that contacts the capacitive touch surface. Accordingly, each button 20 can be configured so that the area of the button that contacts the capacitive touch surface 100 upon application of the force in combination with the electrical properties of the conductive material 30 can cooperate to actuate the capacitive touch surface 100.

In exemplary aspects, the conductive material 30 can comprise an electrically conductive polymer, such as electrically conductive silicone. For example, the conductive material 30 can comprise a composite material comprising polymer with conductive particles dispersed therethrough (e.g., carbon and/or metal). In some cases, feasible conductive materials may include, but are not limited to, conductive silicones, conductive foams, conductive fabrics, combinations thereof, and the like. These materials may be chosen for their ability to maintain electrical conductivity while also providing the desired mechanical properties, such as flexibility and durability. Conductive inks and coatings, which can be applied to various substrates, may also be used to create conductive surfaces or layers within the device. Additionally, composite materials that incorporate conductive particles, such as silver or carbon, into a polymer matrix may be employed to achieve a balance between conductivity and formability. These conductive materials may be selected to provide the appropriate level of responsiveness and tactile feedback when interacting with the capacitive touch surface.

In some aspects, the conductive material 30 can have a conductance on the order of 10^(-6) Siemens per meter (S/m). For example, the conductive material 30 can have a conductance of at least 0.01 S/m, or at least 0.05, or S/m at least 0.1 S/m. In further aspects, the conductive material 30 can have a conductance of at least 1 S/m, or at least 10 S/m, or from about 1 to about 100 S/m. In some aspects, the capacitance of the conductive material 30 can be similar to and mimic the conductivity of human skin.

In some aspects, the device 10 can be free of a power source. For example, the device 10 need not provide a source for generating electrical current or potential to actuate the capacitive touch surface 100.

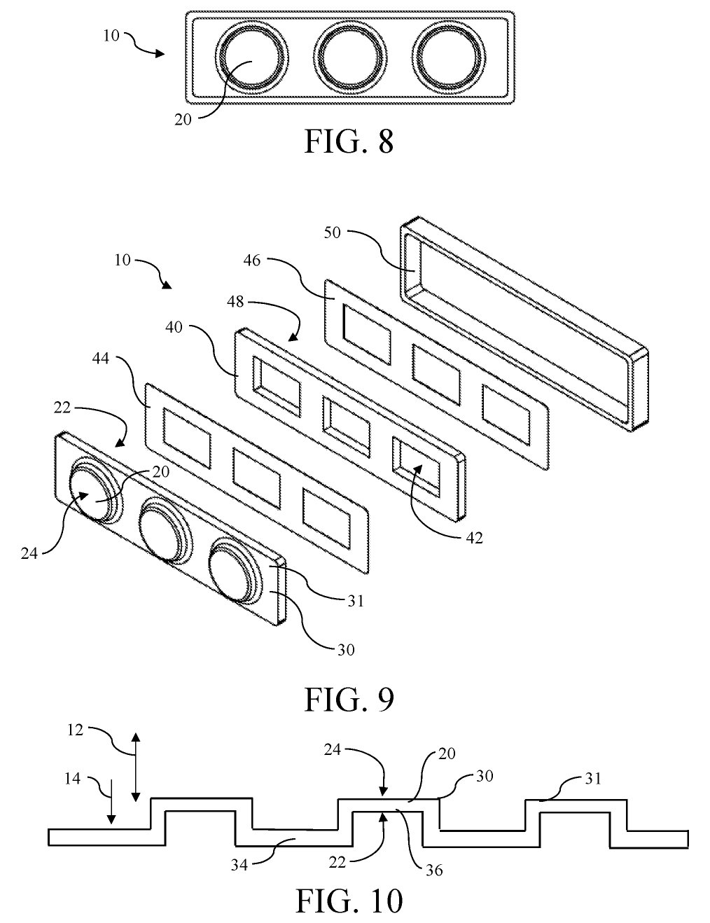

Referring to FIGS. 8-9, in some aspects, the conductive material 30 can comprise an elastomer 31. For example, the elastomer 31 can be configured to elastically deform to permit movement of the first surface 22 of the button 20 from the first position toward the capacitive touch surface 100 (FIG. 1). In further aspects, the elastomer can be resilient so that release of the force permits the elastomer to resiliently return to its pre-deformed position in which the first surface is in the first position (e.g., spaced from the capacitive touch surface 100).

Referring also to FIG. 10, the elastomer 31 can comprise a non-planar profile. For example, the non-planar profile can comprise a first portion 34 and a second portion 36, wherein the first portion that is spaced from the second portion in the first direction 14 along the first axis 12. The second portion 36 can define the first surface 22 of the at least one button 20. Optionally, the conductive material 30 can define the first surface 22 of the at least one button 20 and the second surface 24 of the at least one button.

Referring to FIGS. 8-9, the device 10 can further comprise an insulating material 40 overlying a portion of the conductive material so that when the device is positioned for use with the capacitive touch surface, the insulating material is between the portion of the conductive material and the capacitive touch surface. In this way, contact between the first surface 22 of the button 20 can be partly isolated from the capacitive touch surface 100 and confined within an area at least partly surrounded by the insulating material 40. The insulating material 40 may be designed to provide a barrier between the conductive material and the capacitive touch surface, preventing unwanted electrical contact between the conductive material and the capacitive touch surface. This can help to prevent accidental actuation of the capacitive touch surface, enhancing the reliability and accuracy of the device's operation. In some aspects, the insulating material 40 can define a respective opening 42 at each button 20 of the at least one button. Optionally, the opening of the respective opening 42 can circumferentially surround an area therein. In other aspects, and with reference to FIG. 4, the respective openings 42 can only partly surround an area. For example, the openings 42 can be defined by notches.

In exemplary aspects, the insulating material can comprise electrically insulating polymer, such as, for example, non-conductive silicone. For example, it is contemplated that silicone can have a softness that inhibits damage to the touch surface. It is further contemplated that other non-conductive polymers (e.g., polyethylene terephthalate (PETE), polyethylene, polyester, or polyolefin) or materials can serve as the insulating material 40.

In some cases, the insulating material 40 may be made of a variety of materials, such as plastics, ceramics, or other non-conductive materials. The specific material used for the insulating material can be selected based on a variety of factors, such as the desired level of insulation, durability, cost, and others.

In some embodiments, insulating materials for the device may include, but are not limited to, polyethylene, polyvinyl chloride (PVC), polytetrafluoroethylene (PTFE), commonly known as Teflon, various silicone-based materials, combinations thereof, and the like. These materials may be chosen for their high electrical resistivity and ability to provide effective insulation between the conductive material and the capacitive touch surface. Additionally, materials such as epoxy resins, polyimide films, and glass-filled polymers may also be used due to their insulating properties and mechanical strength. In some cases, the insulating material may be a laminate composed of multiple layers of different materials, each selected for its specific insulating properties and compatibility with the other components of the device. The choice of insulating material may also take into consideration factors such as flexibility, transparency, and resistance to environmental factors like temperature extremes, moisture, and chemical exposure.

Referring to FIGS. 8-9, the device 10 can further comprise an adhesive 44 between and coupling the insulating layer 40 and the conductive material 30. In further aspects, the device 10 can be secured to the capacitive touch surface 100 via an adhesive 46. For example, the adhesive 46 can be provided on a side 48 of the insulating layer 40 opposite the conductive material 30. In further aspects, the device 10 can comprise a release liner that is removable for securing the device 10 to the capacitive touch surface 100.

The device 10 can further comprise a housing 50 (e.g., a frame). The housing 50 can provide structural support to the device 10. The housing 50 can further contain and secure the device 10 to inhibit movement of the conductive material 30 laterally.

It is contemplated that the device 10 can comprise a plurality of buttons 20. For example, the conductive material 30 can be (or comprise) a unitary elastomer body 32, and the plurality of buttons 32 can comprise respective portions 34 of the unitary elastomer body. In other aspects, the device 10 can have only one single button. Optionally, in these aspects, a plurality of such devices 10 can be used with a capacitive touch surface 100.

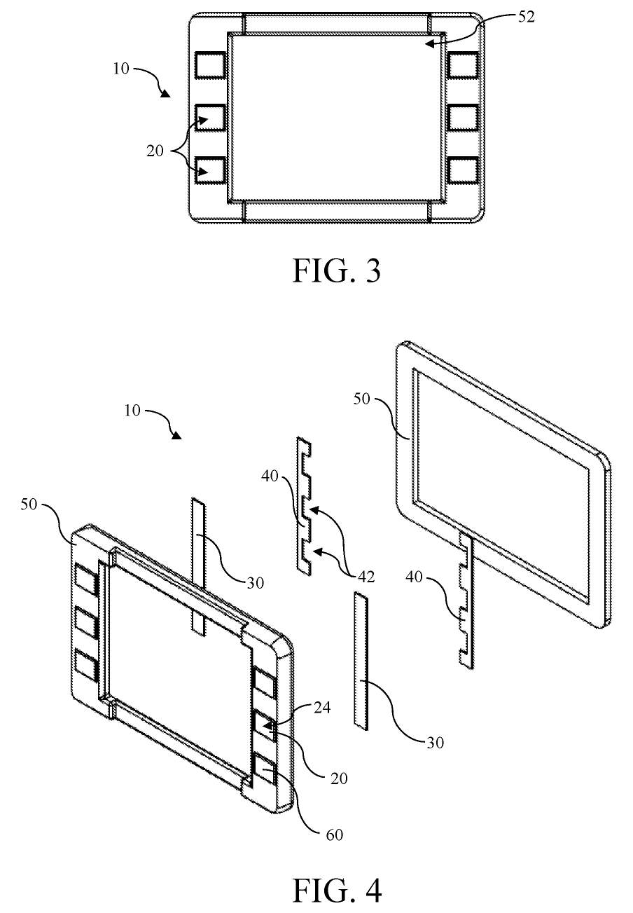

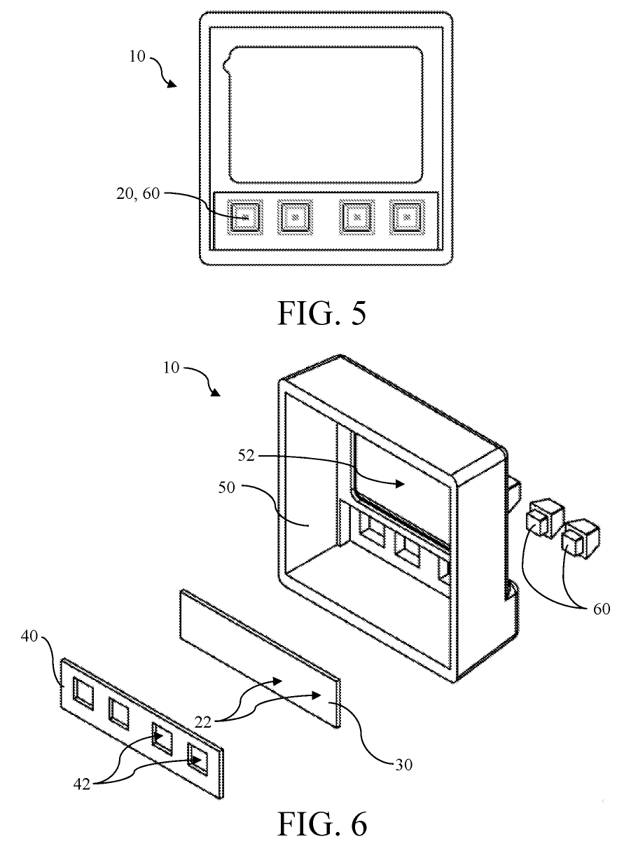

Referring to FIGS. 3-7, at least one button 30 (optionally, each button) can comprise a respective key 60. The key 60 can define the second surface 24 of the respective button 30. The key 60 can be reciprocally movable along the first axis. The reciprocal movement of the key 60 can be configured to effect reciprocal movement of the first surface 22 of the button. For example, as illustrated, the conductive material 30 can extend across a plurality of keys. Depression of the key 60 can displace at least a portion of the conductive material 30 toward capacitive touch surface 100 (FIG. 1). For example, the conductive material 30 can comprise an elastomer, and the reciprocal movement of the key can be configured to elastically deform a region of the elastomer. The insulating material 40 can isolate a portion of the conductive material 30 from the capacitive touch surface beyond the perimeter of the respective opening 42 associated with the button 30.

Referring to FIGS. 3-4, optionally, each key 60 can be coupled to the housing 50 to permit pivotal movement of the key (e.g., about the outer lateral edge). Accordingly, when a user presses the key, the key can pivot relative to the casing. Release of the key 60 can permit return of the key to the position prior to being pressed. In some aspects, the key 60 can be integrally formed with the housing 50 along a shared edge. Accordingly, the pivotal movement of the key can comprise resilient deflection of the key 60 relative to the housing. The key 60 can resiliently return to its unpressed position upon release of the key by the user. Movement of the key 60 toward the capacitive touch surface can cause deformation/deflection of conductive material 30 through the openings 42 of the insulating material 40. The insulating material 40 can provide a spacing of the conductive material 30 from the capacitive touch surface so that release of the key 60 releases pressure on the conductive material 30, permitting the conductive material to resiliently return to an undeformed configuration, spaced from the capacitive touch surface by the thickness of the insulating material 40.

In other aspects, each button 20 can comprise a respective conductive material 30. For example, in these aspects, the conductive material 30 of at least one button 20 can be separate from (not integral with) the conductive material of at least one other button. In some aspects, the conductive material 30 of each button 20 can be separate from (not integral with) the conductive material of each other button. Optionally, in these aspects, the conductive material 30 can be rigid (e.g., comprising a rigid conductive material). In some aspects, the device 10 can comprise a plurality of buttons 20, and the conductive material 30 of each button 20 of the plurality of buttons 20 can be the same material. In other aspects, the device 10 can comprise a plurality of buttons 20, and the conductive material 30 of at least one button 20 can differ from at least one other button of the plurality of buttons. Accordingly, in some aspects, the material can be selected based on the geometry and operation of a particular button. For example, a button with a particularly small contact area can be provided with a conductive material having a relatively high conductivity.

In some aspects, each button 20 can further comprise a biasing element that is configured to cause the at least one button to return to the first position upon release of the force. For example, the biasing element can comprise a spring that acts to return the respective button to a home position in which the first surface 22 of the button is spaced from the capacitive touch surface 100. In other aspects, the conductive material 30 can resiliently return the key 60 to the home position.

In various aspects, at least a portion of the device 10 can be transparent or translucent. For example, in some aspects, at least one button 20 can permit a user to see the capacitive touch surface 100 therethrough. Accordingly, in some aspects, the conductive material 30 can be transparent or translucent. In this way, the device can transmit light from the capacitive touch surface allowing backlighting of the buttons or changing the color of the icons on the button

In some aspects, the device 10 can define at least one window 52 for viewing the capacitive touch surface 100. For example, the housing 50 can define the window 52.

In some aspects, the device 10 can comprise at least one grounding conductor in electrical communication with the conductive material 30. The grounding conductor can comprise a wire or other conducive element. The grounding conductor can provide a grounding connection to a body that grounds the conductive material 30. For example, the ground connection can ground the conductive material 30 to a surface of a capacitive touch device external to the capacitive touch surface, or to a separate grounding element (e.g., a metal base to which the capacitive touch device is coupled).

Referring to FIG. 1, the device 10 can comprise a support structure 70. The support structure can be configured to support the at least one button 20 relative to the capacitive touch surface 100 so that when the at least one button is in the first position, each button of the at least one button overlies, and spaced from, a respective predetermined area of the capacitive touch surface 100. For example, in some aspects, the support structure 70 can couple directly to the capacitive touch surface 100. Optionally, in these aspects, the capacitive touch surface 100 can comprise a housing, and the support structure 70 can couple to the housing. In other aspects, the capacitive touch surface 100 can be mounted to a mounting structure (not shown), and the support structure 70 can couple to the mounting structure, thereby indirectly coupling the support structure 70 to the capacitive touch surface 100. Optionally, the housing 50 can serve as the support structure 70.

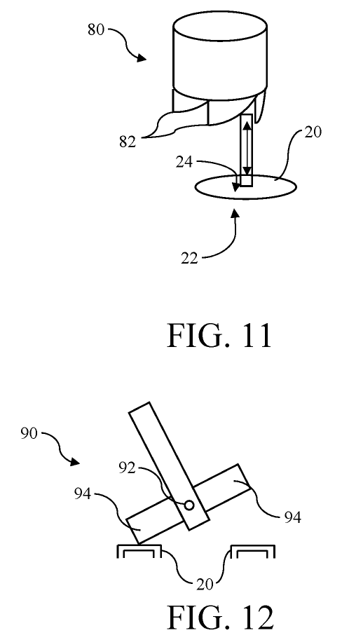

Referring to FIG. 11, in some aspects, the device 10 can comprise a dial 80 that is coupled to a button 20 so that rotation of the dial effects reciprocal movement of at least a portion of the conductive material along the first axis at equal predetermined rotational intervals of the dial. For example, the dial 80 can comprise a lower surface that comprises a plurality of projections 82 equally spaced circumferentially therearound. The plurality of projections 82 can drive a piston 84 reciprocally to actuate the button 20 at predetermined rotational intervals of the dial 80.

In some aspects, the dial can be configured to effect contact between the conductive material 30 and the capacitive touch surface 100 in two different areas, depending on a direction of rotation of the dial. Accordingly, in some aspects, the dial can be configured to selectively actuate two different buttons 20, depending on the direction of rotation. For example, the dial can comprise a clutch that engages upon rotation of the dial in a first rotational direction and disengages upon rotation of the dial in a second, opposite rotational direction. In other aspects, a hinge can selectively engage the dial with a particular button 20 based on the direction of rotational of the dial.

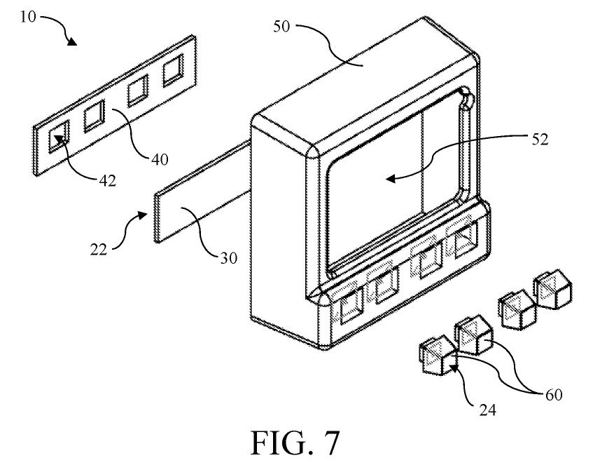

Referring to FIG. 12, in further exemplary aspects, the device 10 can comprise a switch 90 that is pivotable about an axis 92. For example, the switch 90 can pivotably couple to the housing 50 (FIG. 7). In some aspects, the switch 90 can comprise at least one arm 94 extending radially outwardly from the axis 92. For example, the switch 90 can comprise a pair of arms 94 extending from opposed sides of the axis 92. Each arm 94 can be configured to selectively engage a respective button 20. In some aspects, flipping of the switch can cause the respective button 20 to remain in contact with the capacitive touch surface. In other aspects, the switch can permit the button 20 to disengage from the capacitive touch surface. In some optional aspects, the switch can comprise one or more detents that secure the switch in at least one position (e.g., in a first position and in a second position). For example, a protuberance or indentation can be provided on each arm 94 that can interact with a corresponding feature of the cover 50 to secure the switch 90 in a selected position. The tolerances can be selected to permit a user to overcome the locking but also tight enough to hold the switch in position.

In further aspects, the device can comprise a joystick. The joystick can comprise a body that is pivotable about a second axis and a third axis that is transverse (e.g., perpendicular to) the first axis. In some aspects, the joystick can be configured to effect engagement between the conductive material 30 and the capacitive touch surface in different locations depending on the pivotal direction of the joystick. For example, in some aspects, the joystick can be configured to engage different buttons 20 positioned over different regions of the capacitive touch surface. In other aspects, the joystick can comprise one or more conductive material elements coupled thereto, wherein different positions of the joystick effect contact between the one or more conductive material elements coupled thereto and the capacitive touch surface in different regions.

In some aspects, the device can comprise a slider. For example, the slider can be movable in a channel of the housing 50. In some aspects, the slider can serve as a button 20 that is movable relative to the housing 50. For example, the slider can comprise a conductive material 30 that is movable across the touchscreen. In other aspects, the slider can contact a single button 20 in different areas as it moves along the channel. In other aspects, movement of the slider can sequentially actuate a plurality of buttons 20 positioned along the slider’s path of movement.

Optionally, the slider can be biased so that the conductive material 30 associated therewith is disengaged from the capacitive touch surface when released by the user. For example, a spring or diaphragm can bias the slider away from the capacitive touch surface when the slider is not actively being moved. To actuate the slider, the slider can be pushed in the first direction 14, toward the capacitive touch surface to engage the conductive material 30. Accordingly, when the user decides to engage the slider, the slider can be pushed toward the capacitive touch surface to contact the conductive material 30 thereagainst.

In further aspects, the slider and the housing cooperate to permit sliding of the slider relative to the housing only when the slider is displaced in the first direction by a sufficient distance along the first axis. For example, the housing 50 can comprise a plurality of grooves or notches along the channel that prevent motion of the slider when the user is not pressing the slider toward the capacitive touch surface. The grooves or notches can require the user to push the slider in the first direction 14 (FIG. 1) and into engagement with the capacitive touch surface to permit movement of the slider. The slider can be resiliently biased away from the screen so that upon release of the slider, the slider moves away from the screen and is reengaged with the grooves or notches.

In further aspects, various other knobs, switches, slides, joysticks, or other input elements can be included on the device and implemented using the principles disclosed herein. In still further aspects, one or more input elements can be operative to permit use of multi-touch input on capacitive touch surfaces configured to use multi-touch input. For example, a single input device can cause contact with two or more distinct areas of the capacitive touch surface. In other aspects, the device can permit the user to simultaneously actuate two or more input elements (e.g., buttons, dials, switches, sliders, etc.) to use multi-touch input of the capacitive touch surface.

### Assembly

An assembly 200 can comprise a capacitive touch surface 100 and a device 10 overlying the capacitive touch surface and positioned for use therewith. In exemplary aspects, the capacitive touch surface 100 can be a touchscreen. For example, the capacitive touch surface 100 can be a smartphone or tablet. In other aspects, the touchscreen can be a purpose-built touchscreen operably coupled to a computing device. In other aspects, the capacitive touch surface 100 can be a touch pad.

In exemplary aspects, the assembly 200 can comprise the capacitive touch surface with the device 10 adhered thereto. In additional aspects, the device 10 can comprise a support structure 70. The at least one button 20 can be coupled to the support structure 70. The support structure 70 can support the at least one button 20 adjacent the capacitive touch surface 100 so that when first surface 22 of each button of the at least one button is in the first position, each button of the at least one button is proximate to, and spaced from, a respective predetermined area of the capacitive touch surface, and upon application of the force against the second surface 24, the first surface 22 is moved from the first position to a second position (FIG. 2) in which the first surface 22 is in contact with capacitive touch surface.

### System

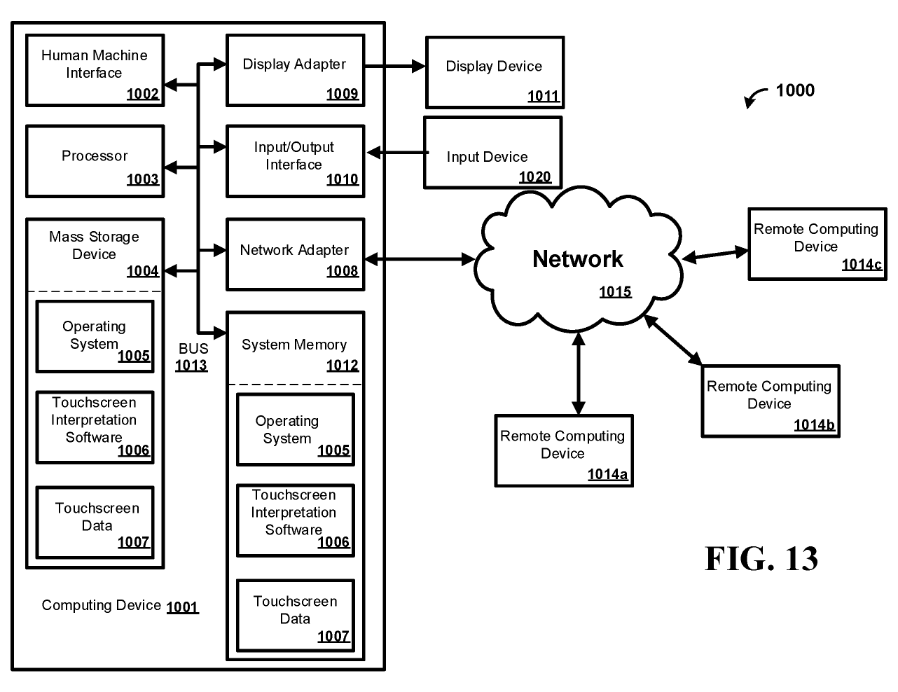

Referring to FIGS. 1 and 13, a system can include a capacitive touch surface 100 and a device 10 overlying the capacitive touch surface and positioned for use therewith. The system can further comprise a computing device 1001 comprising at least one processor (e.g., processor 1003 and memory in communication with the at least one processor (e.g., mass storage device 1004). The memory can have instructions stored thereon that, when executed by the at least one processor, cause the at least one processor to execute one or more programs or routines in response to contact between the first surface 22 of a button 20 and the capacitive touch surface 100.

For example, in some aspects, the device 10 can comprise a dial 80, the dial being coupled to the button so that rotation of the dial effects reciprocal movement of at least a portion of the conductive material along the first axis at equal predetermined rotational intervals of the dial. The computing device 1001 can be configured to associate the contact between the first surface 22 of the button with a rotational displacement of the dial 80. For example, the memory can have instructions stored thereon that, when executed by the at least one processor, cause the at least one processor to receive at least one input from the capacitive touch surface corresponding to contact between the contact surface of the dial; and increment a counter after each input of the at least one input from the capacitive touch surface corresponding to contact between the contact surface of the dial.

### Computing Device

FIG. 13 shows an exemplary computing system 1000 including an exemplary configuration of a computing device 1001 that can be used with the system 300 (FIG. 1). In some aspects, the computing device 1001 can be integral to the capacitive touch surface 100. For example, the capacitive touch surface 100 can be embodied as a tablet or smartphone. In other aspects, the computing device 1001 can be a separate element that is operatively coupled to the capacitive touch surface 100. The computing device 1001 can be configured to receive signals associated with operation of the device (e.g., contact between the first surface 22 of a button 20 on a particular area of the capacitive touch surface 100). The computing device 1001 can further be operative to processing signals associated with operation of the device. For example, the computing device 1001 can be configured to interpret contact between the first surface 22 of a button 20 on a particular area of the capacitive touch surface 100 and/or execute a program or routine in response to contact between the first surface 22 of the button 20 on the particular area of the capacitive touch surface.

The computing device 1001 may comprise one or more processors 1003, a system memory 1012, and a bus 1013 that couples various components of the computing device 1001 including the one or more processors 1003 to the system memory 1012. In the case of multiple processors 1003, the computing device 1001 may utilize parallel computing.

The bus 1013 may comprise one or more of several possible types of bus structures, such as a memory bus, memory controller, a peripheral bus, an accelerated graphics port, and a processor or local bus using any of a variety of bus architectures.

The computing device 1001 may operate on and/or comprise a variety of computer readable media (e.g., non-transitory). Computer readable media may be any available media that is accessible by the computing device 1001 and comprises, non-transitory, volatile and/or non-volatile media, removable and non-removable media. The system memory 1012 has computer readable media in the form of volatile memory, such as random access memory (RAM), and/or non-volatile memory, such as, but not limited to read only memory (ROM).

The computing device 1001 may also comprise other removable/non-removable, volatile/non-volatile computer storage media. The mass storage device 1004 may provide non-volatile storage of computer code, computer readable instructions, data structures, program modules, and other data for the computing device 1001. The mass storage device 1004 may be a hard disk, a removable magnetic disk, a removable optical disk, magnetic cassettes or other magnetic storage devices, flash memory cards, CD-ROM, digital versatile disks (DVD) or other optical storage, random access memories (RAM), read only memories (ROM), electrically erasable programmable read-only memory (EEPROM), and the like.

Any number of program modules may be stored on the mass storage device 1004. An operating system 1005 and touchscreen interpretation software 1006 may be stored on the mass storage device 1004. One or more of the operating system 1005 and/or touchscreen interpretation software 1006 (or some combination thereof) may comprise program modules and the touchscreen interpretation software 1006. Touchscreen data 1007 may also be stored on the mass storage device 1004. The touchscreen data 1007 may be stored in any of one or more databases known in the art. The databases may be centralized or distributed across multiple locations within the network 1015.

In some aspects, the computing device 1001 (server) may be a cloud-based or web-based server without departing from a broader scope of the present disclosure. In some aspects, the remote computing device 1014 may include an implementation of a client instance of the computing device 1001. As such, a user may interact with the computing device 1001 through the remote computing device 1014, e.g., the client instance implemented therein. In some aspects, the remote computing device 1014 may include processors, memory, display interfaces/devices, other output devices, sensors, features of the measuring device, etc., without departing from a broader scope of the present disclosure.

In some aspects, a user may enter commands and information into the computing device 1001 using an input device. Such input devices comprise, but are not limited to, a joystick, a touchscreen display, a keyboard, a pointing device (e.g., a computer mouse, remote control), a microphone, a scanner, tactile input devices such as gloves, and other body coverings, motion sensor, speech recognition, and the like. These and other input devices may be connected to the one or more processors 1003 using a human machine interface 1002 that is coupled to the bus 1013, but may be connected by other interface and bus structures, such as a parallel port, game port, an IEEE 1394 Port (also known as a Firewire port), a serial port, network adapter 1008, and/or a universal serial bus (USB).

A display device 1011 may also be connected to the bus 1013 using an interface, such as a display adapter 1009. It is contemplated that the computing device 1001 may have more than one display adapter 1009 and the computing device 1001 may have more than one display device 1011. A display device 1011 may be a monitor, an LCD (Liquid Crystal Display), light emitting diode (LED) display, television, smart lens, smart glass, and/ or a projector. In addition to the display device 1011, other output peripheral devices may comprise components such as speakers (not shown) and a printer (not shown) which may be connected to the computing device 1001 using Input/Output Interface 1010. Any step and/or result of the methods may be output (or caused to be output) in any form to an output device. In some aspects, any appropriate output from the computing device 1001 may be transmitted to the second computing device 30 and/or the remote computing device 1014 for presentation to a user via the client instance of the computing device 1001. Such output may be any form of visual representation, including, but not limited to, textual, graphical, animation, audio, tactile, and the like. The display device 1011 and computing device 1001 may be part of one device, or separate devices.

The computing device 1001 may operate in a networked environment using logical connections to one or more remote computing devices 1014a,b,c. The other remote computing devices 1014a,b,c may be a personal computer, computing station (e.g., workstation), portable computer (e.g., laptop, mobile phone, tablet device), smart device (e.g., smartphone, smart watch, activity tracker, smart apparel, smart accessory), security and/or monitoring device, a server, a router, a network computer, a peer device, or other common network node, and so on. Logical connections between the computing device 1001 and the remote computing devices may be made using a network 1015, such as a local area network (LAN) and/or a general wide area network (WAN), or a Cloud-based network. Such network connections may be through a network adapter 1008. A network adapter 1008 may be implemented in both wired and wireless environments. Such networking environments are conventional and commonplace in dwellings, offices, enterprise-wide computer networks, intranets, and the Internet. It is contemplated that the remote computing devices can optionally have some or all of the components disclosed as being part of computing device 1001. In various further aspects, it is contemplated that some or all aspects of data processing described herein can be performed via cloud computing on one or more servers or other remote computing devices 1014. Accordingly, at least a portion of the system 1000 can be configured with internet connectivity.

Aspect 1: A device for use with a capacitive touch surface comprising:

at least one button comprising:

a first surface that is configured to contact the capacitive touch surface; and

a second surface opposite the first surface along a first axis,

wherein the at least one button is configured so that:

application of a force against the second surface causes the first surface to move from a first position in a first direction along the first axis; and

release of the force permits the first surface to return to the first position,

wherein the at least one button further comprises a conductive material that is sufficient to actuate the capacitive touch surface upon contact between the conductive material and the capacitive touch surface, wherein the conductive material is positioned between the first surface and the second surface.

Aspect 2: The device of aspect 1, wherein the conductive material comprises an elastomer.

Aspect 3: The device of aspect 2, wherein the elastomer is configured to elastically deform to permit movement of the first surface from the first position toward the capacitive touch surface.

Aspect 4: The device of aspect 3, wherein the elastomer comprises a non-planar profile, the non-planar profile comprising a first portion and a second portion that is spaced from the first portion in the first direction along the first axis, wherein the second portion defines the first surface of the at least one button.

Aspect 5: The device of any one of the preceding aspects, wherein the at least one button comprises a plurality of buttons.

Aspect 6: The device of aspect 5, wherein the conductive material is a unitary elastomer body, wherein the plurality of buttons comprise respective portions of the unitary elastomer body.

Aspect 7: The device of aspect 5, wherein the plurality of buttons each comprise respective conductive material.

Aspect 8: The device of any one of the preceding aspects, wherein the at least one button comprises a key defining the second surface of a button of the at least one button, wherein the key is reciprocally movable along the first axis, wherein the reciprocal movement of the key is configured to effect reciprocal movement of the first surface.

Aspect 9: The device of aspect 8, wherein the at least one button further comprising a biasing element that is configured to cause the at least one button to return to a return position upon release of the force.

Aspect 10: The device of aspect 8, wherein the conductive material comprises a rigid conductive material, wherein the key is coupled to the rigid conductive material.

Aspect 11: The device of aspect 8, wherein the conductive material comprises an elastomer, wherein the reciprocal movement of the key is configured to elastically deform a region of the elastomer.

Aspect 12: The device of any one of the preceding aspects, further comprising an insulating material overlying a portion of the conductive material so that when the device is positioned for use with the capacitive touch surface, the insulating material is between the portion of the conductive material and the capacitive touch surface.

Aspect 13: The device of aspect 12, wherein the insulating material defines a respective opening at each button of the at least one button.

Aspect 14: The device of aspect 12, further comprising an adhesive between the insulating layer and the conductive material.

Aspect 15: The device of aspect 12, further comprising an adhesive on a side of the insulating layer opposite the conductive material.

Aspect 16: The device of any one of the preceding aspects, further comprising a support structure, wherein the at least one button is coupled to the support structure, wherein the support structure is configured to support the at least one button relative to the capacitive touch surface so that when the at least one button is in the first position, each button of the at least one button is proximate to, and spaced from, a respective predetermined area of the capacitive touch surface.

Aspect 17: The device of aspect 16, wherein the support structure is configured to couple to the capacitive touch surface.

Aspect 18: The device of any one of the preceding aspects, wherein the conductive material defines the first surface of the at least one button.

Aspect 19: The device of any one of the preceding aspects, wherein the conductive material defines the second surface of the at least one button.

Aspect 20: The device of any one of the preceding aspects, wherein at least a portion of the device is transparent or translucent.

Aspect 21: The device of any one of the preceding aspects, further comprising a dial, wherein the dial is coupled to the button so that rotation of the dial effects reciprocal movement of at least a portion of the conductive material along the first axis at equal predetermined rotational intervals of the dial.

Aspect 22: The device of any one of the preceding aspects, further comprising a switch that is pivotable about an axis, wherein the switch comprises at least one arm that is configured to apply the force against the second surface of a button of the at least one button that causes the first surface to move from a first position in the first direction along the first axis when the switch is in a first pivotal position.

Aspect 23: The device of any one of the preceding aspects, further comprising a housing, wherein the at least one button comprises a slider, that is axially slidable relative to the housing.

Aspect 24: The device of aspect 23, wherein the slider and the housing cooperate to permit sliding of the slider relative to the housing when the slider is displaced in the first direction by a sufficient distance.

Aspect 25: An assembly comprising:

a capacitive touch surface; and

a device as in any one of the preceding aspects.

Aspect 26: The assembly of aspect 25, wherein the capacitive touch surface is a touchscreen.

Aspect 27: The assembly of aspect 25, wherein the capacitive touch surface is a touch pad.

Aspect 28: The assembly of any one of aspects 25-27, wherein the device is adhered to the capacitive touch surface.

Aspect 29: The assembly of any one of aspects 25-28, wherein the device comprises a support structure, wherein the at least one button is coupled to the support structure, wherein the support structure supports the at least one button adjacent the capacitive touch surface so that:

when the first surface of each button of the at least one button is in the first position, each button of the at least one button is proximate to, and spaced from, a respective predetermined area of the capacitive touch surface, and

upon application of the force against the second surface, the first surface is moved from the first position to a second position in which the first surface is in contact with the capacitive touch surface.

Aspect 30: A system comprising:

an assembly as in any one of aspects 25-29, wherein the device comprises a dial, wherein the dial is coupled to the button so that rotation of the dial effects reciprocal movement of at least a portion of the conductive material along the first axis at equal predetermined rotational intervals of the dial; and

a computing device comprising:

at least one processor; and

memory in communication with the at least one processor, wherein the memory has instructions stored thereon that, when executed by the at least one processor, cause the at least one processor to:

receive at least one input from the capacitive touch surface corresponding to contact between the contact surface of the dial; and

increment a counter after each input of the at least one input from the capacitive touch surface corresponding to contact between the contact surface of the dial.

It should be noted that, the above embodiments are only intended for describing the present disclosure, and should not be interpreted as limitation to the technical solutions of the present disclosure. Although the present disclosure is described in detail in conjunction with the above embodiments, it should be understood by the skilled in the art that, modifications or equivalent substitutions may still be made to the present disclosure by those skilled in the art; and any technical solutions and improvements thereof without departing from the spirit and scope of the present disclosure also fall into the scope of the present disclosure defined by the claims.

What is claimed is:

1. A device for use with a capacitive touch surface comprising:
at least one button comprising:
a first surface that is configured to contact the capacitive touch surface; and
a second surface opposite the first surface along a first axis,
wherein the at least one button is configured so that:
application of a force against the second surface causes the first surface to move from a first position in a first direction along the first axis; and
release of the force permits the first surface to return to the first position,
wherein the at least one button further comprises a conductive material that is sufficient to actuate the capacitive touch surface upon contact between the conductive material and the capacitive touch surface, wherein the conductive material is positioned between the first surface and the second surface.

2. The device of claim 1, wherein the conductive material comprises an elastomer.

3. The device of claim 2, wherein the elastomer is configured to elastically deform to permit movement of the first surface from the first position toward the capacitive touch surface.

4. The device of claim 3, wherein the elastomer comprises a non-planar profile, the non-planar profile comprising a first portion and a second portion that is spaced from the first portion in the first direction along the first axis, wherein the second portion defines the first surface of the at least one button.

5. The device of claim 1, wherein the at least one button comprises a plurality of buttons.

6. The device of claim 5, wherein the conductive material is a unitary elastomer body, wherein the plurality of buttons comprise respective portions of the unitary elastomer body.

7. The device of claim 5, wherein the plurality of buttons each comprise respective conductive material.

8. The device of claim 1, wherein the at least one button comprises a key defining the second surface of a button of the at least one button, wherein the key is reciprocally movable along the first axis, wherein the reciprocal movement of the key is configured to effect reciprocal movement of the first surface.

9. The device of claim 8, wherein the at least one button further comprising a biasing element that is configured to cause the at least one button to return to a return position upon release of the force.

10. The device of claim 8, wherein the conductive material comprises a rigid conductive material, wherein the key is coupled to the rigid conductive material.

11. The device of claim 8, wherein the conductive material comprises an elastomer, wherein the reciprocal movement of the key is configured to elastically deform a region of the elastomer.

12. The device of claim 1, further comprising an insulating material overlying a portion of the conductive material so that when the device is positioned for use with the capacitive touch surface, the insulating material is between the portion of the conductive material and the capacitive touch surface.

13. The device of claim 12, wherein the insulating material defines a respective opening at each button of the at least one button.

14. The device of claim 12, further comprising an adhesive between the insulating layer and the conductive material.

15. The device of claim 12, further comprising an adhesive on a side of the insulating layer opposite the conductive material.

16. The device of claim 1, further comprising a support structure, wherein the at least one button is coupled to the support structure, wherein the support structure is configured to support the at least one button relative to the capacitive touch surface so that when the at least one button is in the first position, each button of the at least one button is proximate to, and spaced from, a respective predetermined area of the capacitive touch surface.

17. The device of claim 16, wherein the support structure is configured to couple to the capacitive touch surface.

18. The device of claim 1, wherein the conductive material defines the first surface of the at least one button.

19. The device of claim 1, wherein the conductive material defines the second surface of the at least one button.

20. The device of claim 1, wherein at least a portion of the device is transparent or translucent.

21. An assembly comprising:
a capacitive touch surface; and
a device as in claim 1, wherein the device is positioned over at least a portion of the capacitive touch surface.
